(19) United States
(12) Patent Application Publication
(10) Pub. No.: US 2005/0259490 A1
(43) Pub. Date: Nov. 24, 2005

(54) Switching control circuit for data driver of display device and method thereof

(76) Inventor: Ki-Myeong Eom, Suwon-si (KR)

Correspondence Address: CHRISTIE, PARKER & HALE, LLP, PO BOX 7068, PASADENA, CA, 91109-7068, US

(21) Appl. No.: 11/126,592

(22) Filed: May 10, 2005

(30) Foreign Application Priority Data
May 18, 2004 (KR) 10-2004-0035136

(51) Int. Cl. G11C 7/00

(52) U.S. Cl. 365/221

(57) ABSTRACT

An input control circuit of a data driver to sequentially transmit a data voltage corresponding to an image signal to a pixel circuit of a light emission device includes first and second shift registers outputting first and second control signals to sequentially apply a data voltage inputted to the data driver; first and second buffer circuits having inverters respectively inverting the first and the second control signals, and outputting first and second switching control signals by adjusting a rising time or a falling time of the first and second control signals; and first and second switches switching an input of the data driver corresponding to the first and second switching control signals.

### CROSS REFERENCE TO RELATED APPLICATION

This application claims priority to and the benefit of Korean Patent Application No. 10-2004-0035136 filed on May 18, 2004 in the Korean Intellectual Property Office, the entire content of which is incorporated herein by reference.

### BACKGROUND OF THE INVENTION

1. Field of the Invention

The present invention relates to a data driver of a display device, and more particularly, it relates to an input control circuit of a data driver in an organic electroluminescent (also referred to as “EL,” hereinafter) display device and a method thereof to control an input of the data driver.

2. Description of the Related Art

In general, an EL display device is a display device that electrically excites phosphorus organic components, and represents an image by voltage-programming or current-programming n×m numbers of organic light emitting cells. As such, an organic EL display device is an advanced display device, which is highly responsive, low power consumptive, and has a large view angle, and thus it is expected to be the next-generation display.

FIG. 1 illustrates a light emission mechanism or an organic light emitting cell (hereinafter, alternatively also referred to as an organic light emitting diode (OLED)) of an organic EL display device.

As shown in FIG. 1, an organic light emitting cell includes an indium tin oxide (ITO) pixel electrode (e.g., an anode), an organic thin film, and one or more metal layers (e.g., a cathode). The organic thin film layer has a multi-layer structure including an emission layer (EML), an electron transport layer (ELT), and a hole transport layer (HTL) to balance electrons and holes and thereby enhance efficiency of light emission. Further, the organic thin film includes an electron injection layer (EIL) and a hole injection layer (HIL).

Methods of driving the organic light emitting cells can include a passive matrix method and an active matrix method. The active matrix method employs a thin film transistor (TFT). In the passive matrix method, an anode and a cathode are formed crossing each other and a line is selected to drive one or more organic light emitting cells. By contrast, in the active matrix method, an indium tin oxide (ITO) pixel electrode (or an anode) is coupled to the TFT and the light emitting cell is driven in accordance with a voltage maintained by the capacitance of a capacitor coupled to a gate of the TFT.

FIG. 2 illustrates a pixel circuit of an organic EL display device.

As shown in FIG. 2, the pixel circuit includes an OLED, a driving transistor DM, a switching transistor SM, and a capacitor Cst. The transistors SM and DM may be provided as PMOS transistors.

A source of the driving transistor DM is coupled to a power voltage Vdd, and the capacitor Cst is coupled between a gate and the source of the driving transistor DM. The capacitor Cst maintains a gate-source voltage at the driving transistor DM for a predetermined period of time, and the switching transistor SM transmits a data voltage from a data line Dm to the driving transistor DM in response to a selection signal from a current scan line Sn.

A cathode of the OLED is coupled to a reference voltage Vss, and the OLED emits light corresponding to a current applied thereto through the driving transistor DM. Herein, the reference voltage Vss coupled to the cathode of the OLED is lower than the power voltage Vdd, and accordingly a ground voltage may be applied thereto.

FIG. 3 illustrates an input control circuit of a data driver in a conventional light emission display device, and FIG. 4 shows a waveform showing that outputs from a shift register in the input control circuit of the data driver in FIG. 3 are overlapped.

Referring to FIG. 3 and FIG. 4, the input control circuit of the data driver in the conventional light emission display device includes shift registers 311 and 312, and switches 321 and 322.

The shift registers 311 and 312 respectively output a first control signal and a second control signal for sequentially applying a data voltage Dm inputted to the data driver to sequentially transmit the data voltage Dm corresponding to an image signal to the pixel circuits or pixels of the light emission display device.

The switches 321 and 322 switch inputs of the data driver corresponding to the first control signal and the second control signal, and provide the switched inputs to an active area. The active area can be a panel 330 of FIG. 3.

In general, a conventional shift register (e.g., the shifter register 311) outputs SR(n) as a first output, and a conventional shift register (e.g., the shifter register 312) outputs SR(n+1) as a second output. However, there is a signal overlap period where the SR(n) and the SR(n+1) are overlapped with each other as shown in FIG. 4.

In the case that the SR(n) and the SR(n+1) are respectively inputted as control signals to the first switch 321 and the second switch 322, these switches 321 and 322 are concurrently turned off (or simultaneously turned off for a period of time) in the signal overlap period, and consequently wrong data may be inputted to the panel 330. Further, input loads may be unbalanced. As such, the wrong data may cause the data voltage to be raised or lowered, and an input of the panel 330 may be wrong.

### SUMMARY OF THE INVENTION

It is an aspect of the present invention to provide an input control circuit of a data driver of a display device or a light emission display device that stably transmits a data voltage to a pixel circuit and thereby precisely controls an input load of the pixel circuit.

In addition, an aspect of the present invention provides a buffer circuit of the light emission display device to prevent switching signals of the data driver outputted from a shift register from being overlapped.

One exemplary embodiment of the present invention provides an input control circuit of a data driver in a display device for controlling an input of the data driver to transmit a data voltage of an image signal to a display panel of the display device, the input control circuit having a first shift register and a second shift register; a first buffer circuit and a second buffer circuit; and a first switch and a second switch. The first and second shift registers respectively output a first control signal and a second control signal for sequentially applying the data voltage transmitted by the data driver. The first and second buffer circuits have a plurality of inverters for respectively inverting the first and second control signals, and respectively outputting a first switching control signal and a second switching control signal having a rising time or a falling time of the first and second control signals respectively adjusted. The first and second switches respectively switch the input of the data driver corresponding to the first and second switching control signals.

Each of the first and second buffer circuits may include a first inverter and one or more second inverters. The first inverter receives at least one of the first control signal and a second control signal having an overlapped period in the rising time or the falling time of each, inverts the at least one of the received signals, and outputs the at least one of the inverted signals. The one or more second inverters adjust one of the rising time and the falling time of the at least one of the first and second control signals outputted from the first inverter to be fast and another one of the rising time and the falling time of the at least one of the first and second control signals to be slow, and output at least one of the first and second switching control signals.

The plurality of inverters may alternately adjust one of the rising time and the falling time of the first and second control signals to be fast and the other to be slow.

The first and second switching control signals may rise or fall depending on whether a number of the inverters is an odd number or an even number.

The plurality of inverters may include N-type or P-type thin film transistors (TFTs) arranged in series.

The sizes of the N-type or P-type TFTs may be sequentially changed.

The sequentially changed sizes of the N-type or P-type TFTs may be respectively different.

The plurality of inverters may includes a TFT having at least a dual or triple gate.

One exemplary embodiment of the present invention includes a buffer circuit of a display device having a data driver for sequentially transmitting a data voltage of an image signal to a display panel, the buffer circuit having a first inverter and one or more second inverters. The first inverter receives at least lone of a first control signal and a second control signal that are overlapped in a rising time or a falling time, inverts the at least one of the first control signal and the second control signal, and outputs the at least one of the inverted signals. The one or more second inverters adjusts one of the rising time and the falling time of the at least one of the first control signal and the second control signal to be fast and the other to be slow, and outputs the at least one of the first control signal and the second signal as at least one of a first switching control signal and a second switching control signal.

In another exemplary embodiment of the present invention, a method of controlling an input of a data driver to transmit a data voltage of an image signal to a display panel of a display device is provided. In the method, a) a first control signal and a second control signal that are overlapped with each other in a rising time or a falling time are respectively outputted to sequentially apply the data voltage transmitted by the data driver; b) the first control signal and the second control signal are inverted to adjust one of the rising time and the falling time of the first and second control signals to be fast and the other to be slow, and the inverted signals are outputted; c) the outputted first and second control signals are respectively inverted to adjust the one of the rising time and the falling time adjusted to be fast in b) to be slow and the another one adjusted to be slow in b) to be fast, and the inverted signals are outputted as a first switching control signal and a second switching control signal; d) the first switching control signal and the second switching control signal are adjusted so as not to overlap each other; and e) the first switching control signal and the second switching control signal that are not overlapped with each other are sequentially inputted to a display panel of the display device.

In the method, b) and c) may be repeated.

In the method, the rising time and the falling time of the first control signal and the second control signal may be controlled by inverters having sizes that are sequentially changed.

### BRIEF DESCRIPTION OF THE DRAWINGS

The accompanying drawings, together with the specification, illustrate exemplary embodiment(s) of the present invention, and, together with the description, serve to explain the principles of the present invention.

FIG. 1 shows a light emission mechanism of an organic EL display device.

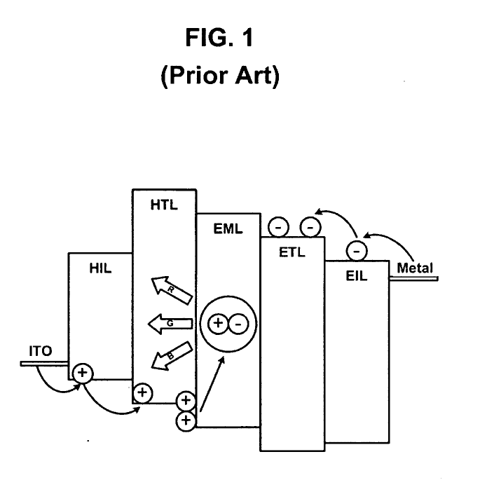

FIG. 2 is a pixel circuit of an organic EL display device.

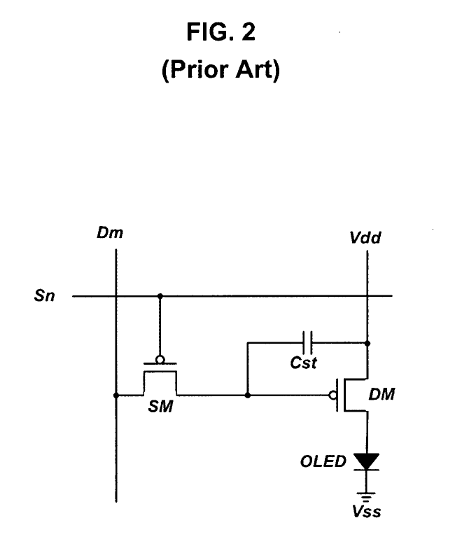

FIG. 3 is an input control circuit of a data driver of a conventional light emission display device.

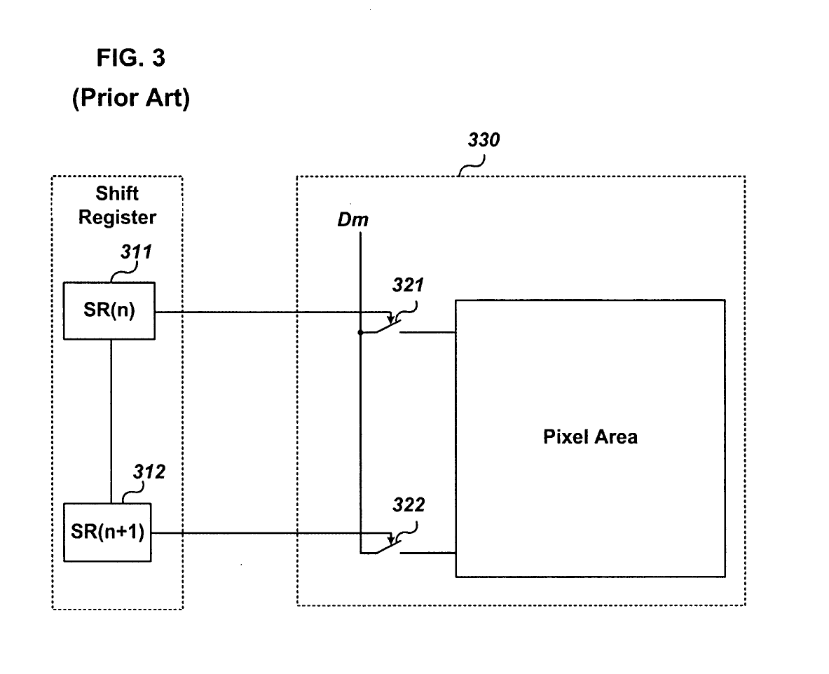

FIG. 4 is waveforms showing that outputs of a shift register in input control circuit of the data driver in FIG. 3 are overlapped.

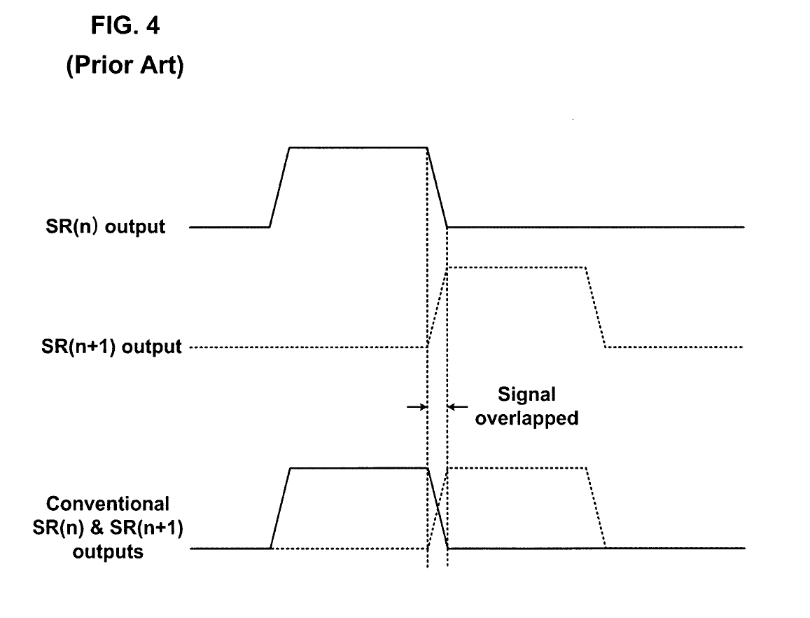

FIG. 5 is a schematic block diagram of an organic EL display device according to an exemplary embodiment of the present invention.

FIG. 6 is a general organic EL display panel employing an active driving method using a TFT according to an exemplary embodiment of the present invention.

FIG. 7 schematically illustrates an input control circuit of a data driver in a light emission device according to an exemplary embodiment of the present invention.

FIG. 8 illustrates an input control circuit of a data driver in a light emission device according to an exemplary embodiment of the present invention.

FIG. 9 shows outputs of the buffer compensating the overlapped outputs of the shift register in the input control circuit of the data driver in FIG. 8

FIG. 10 illustrates an input control circuit of a data driver in a light emission device according to another exemplary embodiment of the present invention.

FIG. 11 shows a simulation result of an input control circuit in a data driver of a light emission device according to an exemplary embodiment of the present invention.

FIG. 12 shows a simulation result regarding threshold voltage variation in an input control circuit of a data driver in a light emission device according to an exemplary embodiment of the present invention.

### DETAILED DESCRIPTION

In the following detailed description, only certain exemplary embodiments of the present invention are shown and described, simply by way of illustration. As those skilled in the art would realize, the described embodiments may be modified in various different ways, all without departing from the spirit or scope of the present invention. Accordingly, the drawings and description are to be regarded as illustrative in nature, and not restrictive. There may be parts shown in the drawings, or parts not shown in the drawings, that are not discussed in the specification as they are not essential to a complete understanding of the invention. Like reference numerals designate like elements.

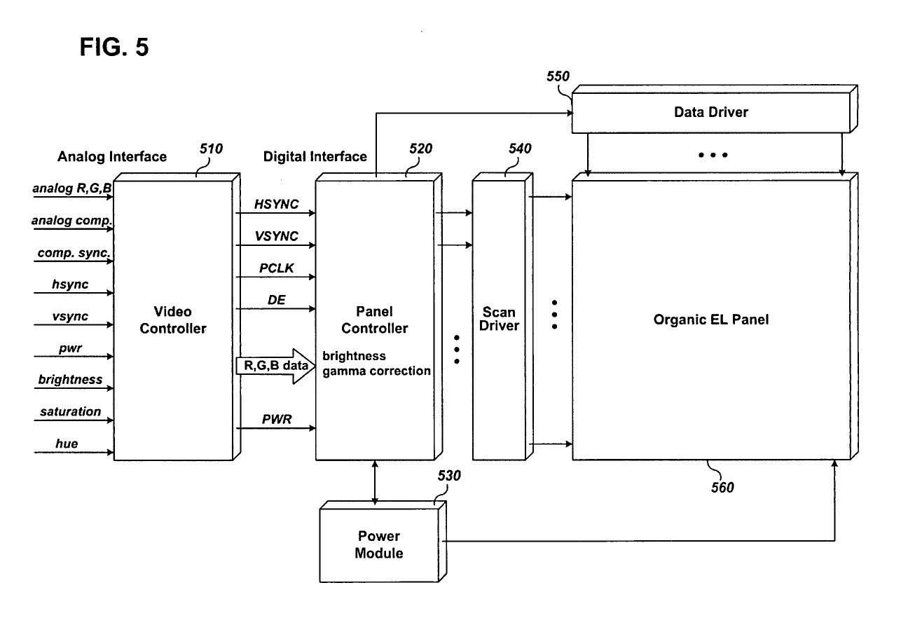

FIG. 5 illustrates an organic EL display device according to an embodiment of the present invention using a schematic block diagram.

As shown in FIG. 5, the organic EL display device includes a video controller 510, a panel controller 520, a power module 530, a scan driver 540, a data driver 550, and an organic EL panel 560. The scan driver 540 and the data driver 550 provide the organic EL panel 560 in a column direction and a row direction respectively with signals that are passed through an analog interface and a digital interface.

In detail, analog signals including red, green, and blue (RGB) signals and synchronized signals are inputted to the video controller 510 and are converted into digital signals, and the panel controller 520 controls the digital signals to be sequentially inputted to the scan driver 540 and the data driver 550. The organic EL panel 560 displays an image by voltage-driving or current-driving the n×m organic emitting cells using signals inputted to the scan driver 540 and the data driver 550 and a power applied to the power module 530.

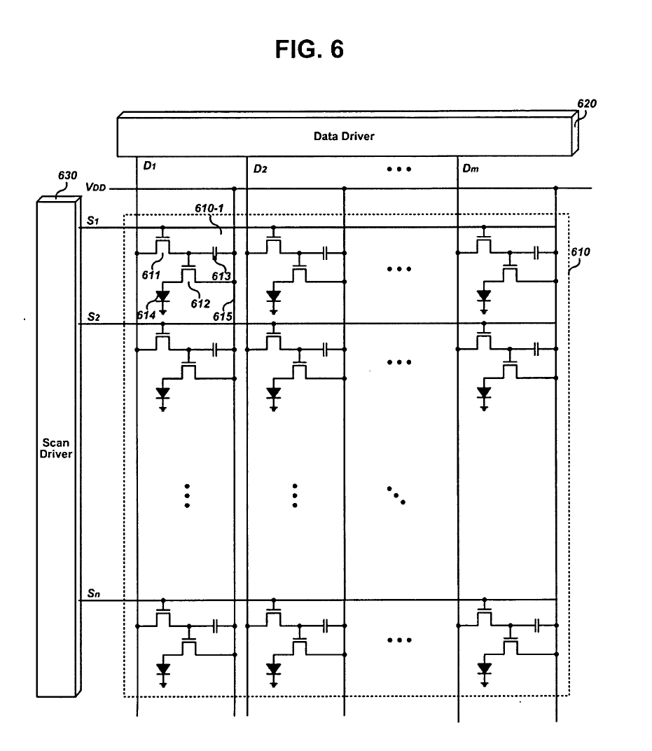

In more detail, FIG. 6 illustrates a typical organic EL panel 610 employing an active driving method using a TFT according to an embodiment of the present invention.

As shown in FIG. 6, the organic EL display device includes an organic EL panel 610, a data driver 620, and a scan driver 630.

The organic EL panel 610 includes m numbers of data lines D1 to Dm arranged in rows, n numbers of scan lines S1 to Sn arranged in columns, and n×m pixel circuits. The data lines D1 to Dm transmit data signals as image signals to the pixel circuits, and the scan lines S1 to Sn transmit selection signals to the pixel circuits. Herein, the pixel circuits are formed in a single pixel area 610-1 defined by two adjacent data lines D1 to Dm and two adjacent scan lines S1 to Sn, and includes transistors 611 and 612, a capacitor 613, and an OLED 614. Herein, the reference numeral 615 represents a power voltage Vdd (or a power line for transmitting the power voltage Vdd).

The scan driver 630 sequentially applies the selection signals to the scan lines S1 to Sn, and the data driver 620 applies a data voltage corresponding to an image signal to the data lines D1 to Dm.

Further, the scan driver 630 and/or the data driver 620 may be coupled to the organic EL panel 610, or may be attached to the organic EL panel 610 as a chip, and then installed to a tape carrier package (TCP) to which the organic EL panel 610 is coupled. Also, the scan driver 630 and/or the data driver 620 may be attached to the organic EL panel 610 as a chip and then installed to a flexible printed circuit (FPC) or a film to which the organic EL panel 610 is coupled.

On the other hand, the scan driver 630, and/or the data driver 620 may be directly attached to a glass substrate of the organic EL panel 610, and they may be replaced with a driving circuit formed on a glass substrate, wherein the driving circuit is layered in a like manner as the scan line, the data line, and the TFT are layered.

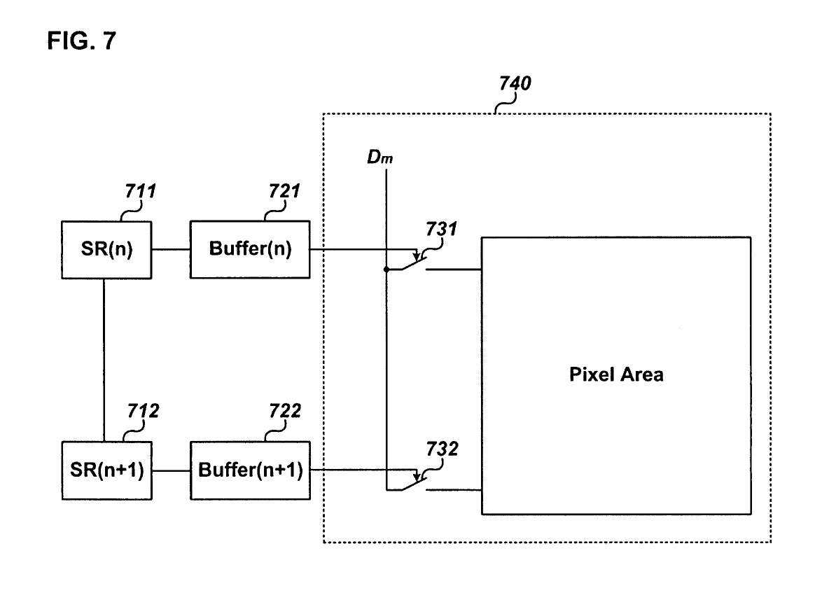

FIG. 7 schematically illustrates an input control circuit of a data driver in a light emission display device according to an embodiment of the present invention.

As shown in FIG. 7, the input control circuit of the data driver in the light emission display device according to the embodiment of the present invention includes buffer circuits 721 and 722 coupled between the shift registers 711 and 712 and the switches 731 and 732. The buffer circuits 721 and 722 remove overlapped output signals respectively outputted from the shift registers 711 and 712 to thereby stably provide the data voltage Dm inputted from the data driver to the organic EL panel 740. Herein, the shift registers 711 and 712 shift a first signal level to a second signal level and output a result signal so as to provide inputs that are adjacent to each other and have the same time interval.

According to an embodiment of the present invention, a buffer circuit includes at least two inverters.

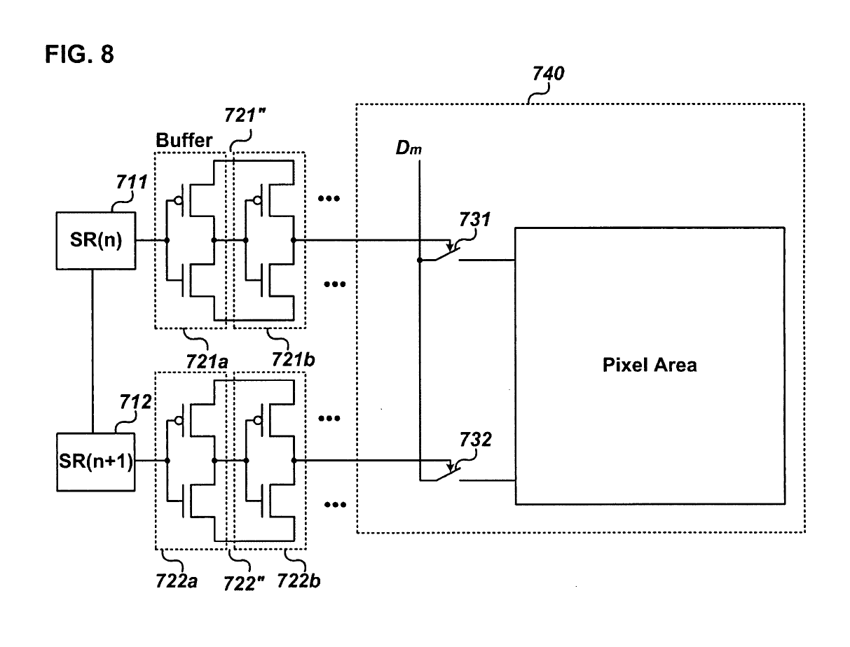

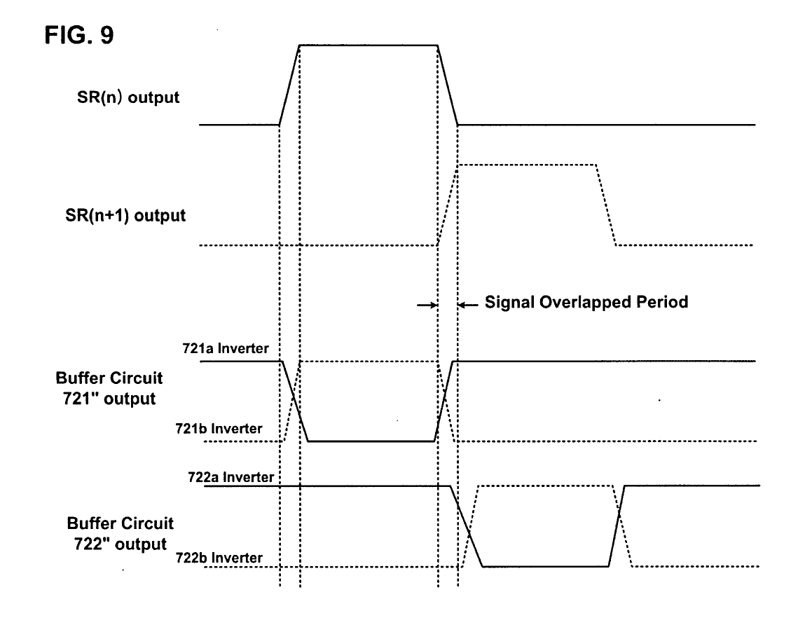

In more detail, FIG. 8 illustrates an input control circuit of a data driver in a light emission display device according to an embodiment of the present invention, and FIG. 9 shows waveforms of buffers compensating an overlapped output of a shift register in the input control circuit of the data driver in FIG. 8.

As shown in FIG. 8, the input control circuit of the data driver in the light emission display device according to the embodiment of the present invention sequentially controls inputs of the data driver to sequentially transmit a data voltage corresponding to an image signal to the pixel circuits of the light emission display device, and includes shift registers 711 and 712, buffer circuits 721″ and 722″, and switches 731 and 732, the buffer circuits 721″ and 722″ respectively including at least two inverters 721a and 721b and 722a and 722b arranged in series.

The shift registers 711 and 712 respectively output a first control signal and a second control signal to sequentially apply a data voltage inputted by the data driver to the pixel circuit.

Further, each of the buffer circuits 721″ or 772″ includes the at least two inverters 721a and 721b or 722a and 722b for inverting the first and/or second control signals, and converting the first and/or the second control signals into first and/or a second switching control signals and outputs the converted signal(s) so as to control the first and the second control signals to maintain a predetermined interval therebetween.

In particular, the first control signal and the second control signal outputted from the shift registers 711 and 712 have an overlapped signal period, but the rising timing or falling timing of the first and the second control signals are adjusted using the at least two inverters 721a and 722a so as to input signals that are not overlapped to the organic EL panel 740. That is, outputs of the at least one of the two inverters 721a and/or 722a are controlled by the second inverter (e.g., 721b or 722b) to be used as a load of the output of the first inverter (e.g., 721a and 722a), and repeats speeding up of the rising time or the falling time of the output signal of the first inverter (e.g., 721a and 722a) and/or a slowing down of the rising time or the falling time of output signal of the second inverter (e.g., 721b or 722b). Therefore, the first and second switching control signals which are output signals of the two buffer circuits 721″ and 722″ are as shown in FIG. 9, and the output signals are inputted to the switches 731 and 732 without generating an overlapped signal period therebetween, and thus rising and falling problems of the data voltage according to a conventional input control method can be solved.

Here, a predetermined interval is formed between the first switching control signal and the second switching control signal, and the first switching control signal and the second switching control signal are not overlapped in the predetermined interval when these signals are respectively rising or falling.

Also, the plurality of inverters alternately control one of the rising time and the falling time of the first control signal and the second control signal to be fast and the other to be slow. The rising time or the falling time of the switching control signals are determined depending on whether the number of inverters provided in the buffer circuit is an odd number or an even number. Further, the plurality of inverters includes N-type or P-type TFTs arranged in series, and the sizes of the respective TFTs can be alternately big and small, or can become gradually smaller.

In addition, the switches 731 and 732 switch an input of the data driver corresponding to the first and second switching control signals so as to stably provide the panel 740 with a data voltage.

In operation, a method of controlling an input of a data driver according to an exemplary embodiment of the present invention is provided below. The method sequentially transmits a data voltage corresponding to an image signal to pixel circuits of the light emission display device. Initially, in the method, first and second control signals overlapped during a rising time or a falling time are respectively outputted to sequentially apply the data voltage inputted to the data driver.

Next, the first and the second control signals are inverted so that one of the rising time and the falling time of the signals is fast and the other is slow, and the inverted control signals are outputted. Then, the first and second control signals are inverted again so as to invert the speeds of the rising time and the falling time to be opposite, and the inverted signals are outputted.

By adjusting the rising time and the falling time of the first and second control signals, these signals can be outputted without being overlapped, and be sequentially inputted to a display panel.

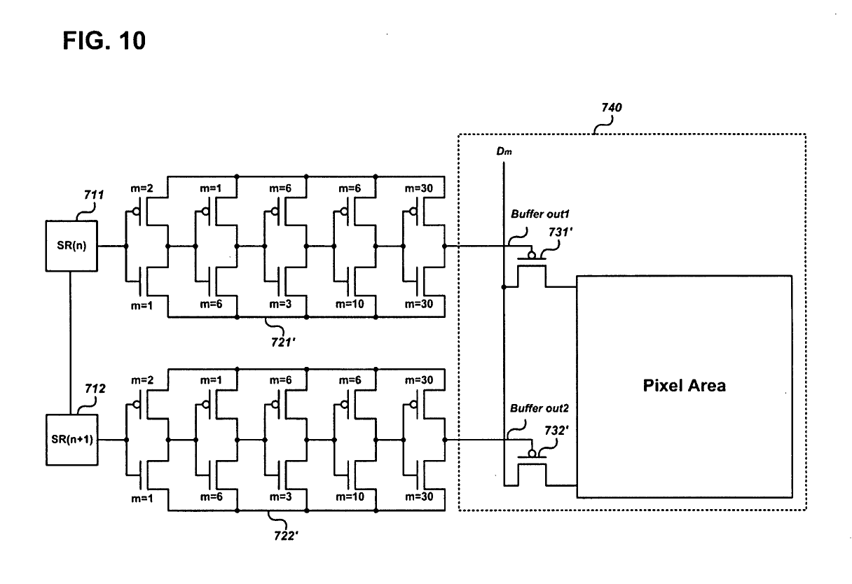

FIG. 10 illustrates an input control circuit of a data driver in a light emitting device according to another embodiment of the present invention.

Referring to FIG. 10, the input control circuit of the data driver in the light emitting device according to the another embodiment of the present invention has five inverters using the P-type TFTs 731′ and 732′ instead of using the switches 731 and 732 of FIG. 8. In addition, the five inverters employ dual gate TFTs that are coupled in series to form the buffer circuits 721′ and 722′ of FIG. 10. The ‘m’ shown in FIG. 10 is a comparative number representing the size of the TFTs. For instance, in a case that a length L and a width W of a TFT is respectively 10 μm, the size of the TFT can be represented by a comparative number 1 (m=1). In a like manner, when the value of m is set to be 3, the width W of the TFT may be 30 μm while the length L of the TFT may be 10 μm.

In particular, when the outputs of the shift registers 711 and 712 are inputted to the first inverter, the first inverter outputs a signal that rises fast and falls slow. When the signal outputted from the first inverter is inputted to a second inverter, the second inverter outputs a signal that rises slow and falls fast. Herein, the second inverter becomes the load of the first inverter, and thus the speed of the rising time and the falling time are changed depending on the value of m. In a like manner, the third inverter outputs a signal that rises fast and falls slow, and the fourth inverter outputs a signal that rises slow and falls fast. In a like manner, the fifth inverter outputs a signal that rises fast and falls slow.

Therefore, output signals of the first buffer and the second buffer circuits 721′ and 722′ are inputted to the switches 731′ and 732′ without generating an overlapped signal period therebetween, and thus rising and falling problems of the data voltage according to a conventional input control method can be solved.

As described, in the method using the buffer circuits 721′ and 722′ to prevent the first and second control signals from being overlapped, the plurality of inverters are arranged in series, and the sizes thereof are adjusted by alternately arranging a large TFT and a small TFT. In the buffer circuit of FIG. 10, the TFT includes a P-type or N-type TFT, and the sizes of the TFTs are the same or gradually larger, but the present invention is not thereby limited. For example, the sizes of the TFTs can be set to be gradually smaller.

FIG. 8 and FIG. 10 illustrate the input control circuit of the data driver in the light emission display device according to the embodiments of the present invention, and the buffer circuit according to an embodiment of the present invention can be used when output signals of two adjacent shift registers are overlapped.

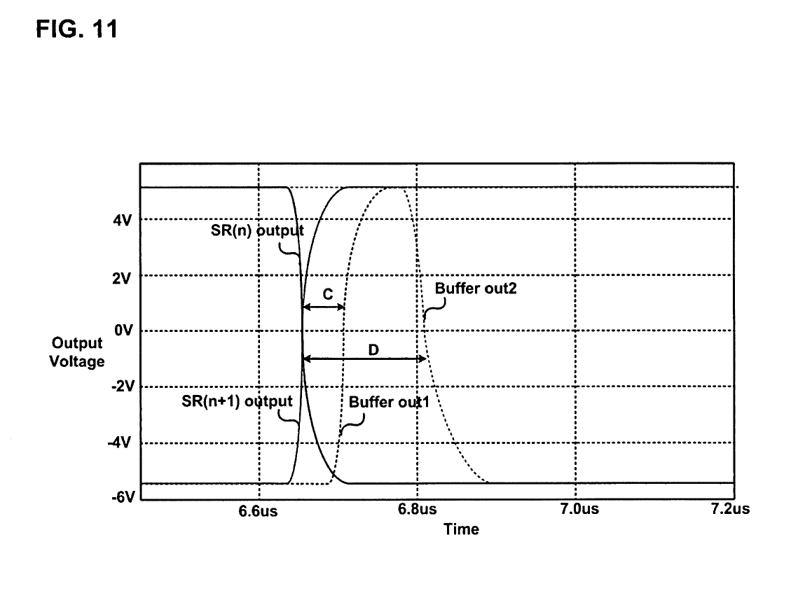

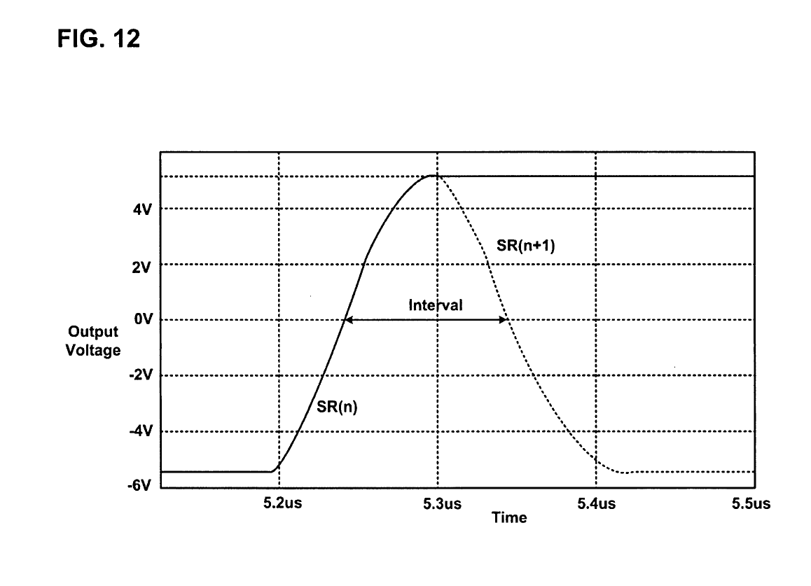

FIG. 11 shows a simulation result of an input control circuit of a data driver in a light emission display device according to an embodiment of the present invention, and FIG. 12 shows a simulation result of threshold voltage variation in an input control circuit of a data driver in a light emission display device according to an embodiment of the present invention.

The output waveforms of the buffer circuits shown in FIG. 9 result from the simulation of the input control circuit of the data driver shown in FIG. 11. As can be seen in FIG. 9, the use of the at least two inverters in this embodiment effectively removes the overlap of the output signals.

Further, variation of a threshold voltage Vth at a TFT forming an inverter of the buffer circuit and mobility variation can be simulated, and these two simulations show the same results. In other words, the threshold voltage variation and the mobility variation do not generate the overlapped signal period. That is, FIG. 12 shows an exemplary result of the threshold voltage (Vth) variation simulation. As shown in FIG. 12, a first control signal of SR(n) and a second control signal of SR(n+1) have an interval therebetween, and no overlapped signal period is generated in the interval.

In general and according to exemplary embodiments of the present invention, switching signals of the data driver outputted from the shift registers are prevented from being overlapped, thereby preventing improper rising or falling of the data voltage. Thus the data voltage inputted from the data driver of the light emission device can be stably transmitted to the pixel circuit.

In addition, the present invention provides an improved organic EL display device by precisely controlling the load of the data inputted to the pixel circuit.

While the invention has been described in connection with certain exemplary embodiments, it is to be understood by those skilled in the art that the invention is not limited to the disclosed embodiments, but, on the contrary, is intended to cover various modifications included within the spirit and scope of the appended claims and equivalents thereof.

1. An input control circuit of a data driver in a display device for controlling an input of the data driver to transmit a data voltage of an image signal to a pixel circuit of the display device, the input control circuit comprising:
a first shift register and a second shift register for respectively outputting a first control signal and a second control signal for sequentially applying the data voltage transmitted by the data driver;
a first buffer circuit and a second buffer circuit having a plurality of inverters for respectively inverting the first and second control signals, and respectively outputting a first switching control signal and a second switching control signal having a rising time or a falling time of the first and second control signals respectively adjusted; and
a first switch and a second switch for respectively switching the input of the data driver in response to the first and second switching control signals.

2. The input control circuit according to claim 1, wherein each of the first and second buffer circuits comprises:
a first inverter for receiving at least one of the first control signal and the second control signal that are overlapped with each other in the rising time or the falling time, inverting the at least one of the first and second control signals, and outputting the at least one of the first and second control signals; and
one or more second inverters for adjusting one of the rising time and the falling time of the at least one of the first and second control signals outputted from the first inverter to be fast and another one of the rising time and the falling time of the at least one of the first and second control signals to be slow, and outputting at least one of the first and second switching control signals.

3. The input control circuit according to claim 2, wherein the second inverters comprise at least two inverters.

4. The input control circuit according to claim 1, wherein the plurality of inverters alternately adjusts one of the rising time and the falling time of the first and the second control signals to be fast and another one of the rising time and the falling time of the first and second control signals also to be slow.

5. The input control circuit according to claim 4, wherein the first and second switching control signals rise or fall depending on whether a number of the inverters is an odd number or an even number.

6. The input control circuit according to claim 1, wherein the plurality of inverters include N-type or P-type thin film transistors (TFTs) arranged in series.

7. The input control circuit according to claim 6, wherein sizes of the N-type or P-type TFTs are sequentially changed.

8. The input control circuit according to claim 7, wherein the sequentially changed sizes of the N-type or P-type TFTs are respectively different.

9. The input control circuit according to claim 1, wherein the plurality of inverters includes a TFT having at least a dual or triple gate.

10. A buffer circuit of a display device having a data driver for sequentially transmitting a data voltage of an image signal to a pixel circuit, the buffer circuit comprising:
a first inverter for receiving at least one of a first control signal and a second control signal that are overlapped with each other in a rising time or a falling time, inverting the at least one of the first control signal and the second control signal, and outputting the at least one of the first control signal and the second control signal; and
one or more second inverters adjusting one of the rising time and the falling time of the at least one of the first control signal and the second control signal to be fast and another one of the rising time and the falling time of the at least one of the first control signal and the second control signal to be slow, and outputting the at least one of the first control signal and the second control signal as at least one of a first switching control signal and a second switching control signal.

11. The buffer circuit according to claim 10, wherein the first switching control signal and the second switching control signal rise or fall depending on whether a number of the inverters is an odd number or an even number.

12. The buffer circuit according to claim 10, wherein the first and second inverters include N-type or P-type thin film transistors (TFTs) arranged in series.

13. The buffer circuit according to claim 12, wherein sizes of the N-type or P-type TFTs are sequentially changed.

14. The buffer circuit according to claim 13, wherein the sizes of the sequentially changed TFTs are respectively different.

15. The buffer circuit according to claim 10, wherein the first inverter or the second inverter includes a TFT having at least a dual or triple gate.

16. The buffer circuit according to claim 10, wherein the second inverters comprise at least two inverters.

17. A method of controlling an input of a data driver to transmit a data voltage of an image signal to a pixel circuit of a display device, the method comprising:
a) respectively outputting a first control signal and a second control signal that are overlapped with each other in a rising time or a falling time to sequentially apply the data voltage transmitted by the data driver;
b) respectively inverting the first control signal and the second control signal and adjusting one of the rising time and the falling time of the first and second control signals to be fast and another one of the first and second control signals to be slow, and outputting the first and second control signals;
c) respectively inverting the first and second control signals outputted in b) and adjusting the one of the rising time and the falling time adjusted to be fast in b) to be slow and adjusting the another one of the rising time and the falling time adjusted to be slow in b) to be fast, and outputting the first and second control signals;
d) outputting the first and second control signals respectively as a first switching control signal and a second switching control signal such that the first and second control signals are adjusted so as not to overlap each other; and
e) sequentially inputting the first switching control signal and the second switching control signal that are not overlapped to the display panel.

18. The method according to claim 17, wherein b) and c) are repeated.

19. The method according to claim 17, wherein the rising time and the falling time of the first control signal and the second control signal are controlled by inverters having sizes that are sequentially changed.

20. The method according to claim 19, wherein the inverters are formed by TFTs having at least dual or triple gates.
